(19) United States
(12) Patent Application Publication
(10) Pub. No.: US 2024/0178353 A1
(43) Pub. Date: May 30, 2024

(54) DISPLAY PANEL AND MANUFACTURING METHOD THEREOF

(71) Applicant: XIAMEN EXTREMELY PQ DISPLAY TECHNOLOGY CO., LTD., Xiamen (CN)

(72) Inventors: Gang MA, Xiamen (CN); Chen-Ke HSU, Xiamen (CN)

(21) Appl. No.: 18/436,050

(22) Filed: Feb. 8, 2024

Related U.S. Application Data
(63) Continuation-in-part of application No. PCT/CN2022/071846, filed on Jan. 13, 2022.

(30) Foreign Application Priority Data
Dec. 15, 2023 (CN) 202323438182.4

(51) Int. Cl. H01L 33/54; H01L 25/075; H01L 33/10; H01L 33/58

(52) U.S. Cl. CPC H01L 33/54; H01L 25/0753; H01L 33/10; H01L 33/58; H01L 2933/005; H01L 2933/0058

(57) ABSTRACT

The present application provides a display panel and a manufacturing method thereof. The display panel includes: a driving substrate, a plurality of chips, a dielectric layer, and a plurality of encapsulating colloids. Each of the plurality of chips and each of the plurality of encapsulating colloids are correspondingly arranged, and the encapsulating colloid covers the chip. The dielectric layer is disposed on outer peripheries of the encapsulating colloids. The encapsulating colloid includes a substrate and a curved lens connected to each other, the substrate covers the chip, and the curved lens is disposed on a side of the substrate away from the chip.

### CROSS-REFERENCE TO RELATED APPLICATIONS

This application is a continuation-in-part of International Application No. PCT/CN2022/071846, filed on Jan. 13, 2022, and claims to priority Chinese Patent Application No. 202323438182.4, filed on Dec. 15, 2023. Both of the aforementioned patent applications are hereby incorporated by reference in their entireties.

### TECHNICAL FIELD

Embodiments of the present application relate to a technical field of display technology, and more particularly, to a display panel and a manufacturing method thereof.

### BACKGROUND

Currently, most flat panel displays have a wide-angle display, of which viewing angles are generally greater than 120° or more. In certain special fields, such as head up display (HUD) field, in order to avoid a user from obtaining information by frequently moving viewings, it is necessary to present displayed content in a front viewing angle range of the user. Therefore, there is a need for a flat panel display having a smaller viewing angle.

However, in a display panel, lights emitted from a chip are generally diverged which is not only unfavorable to achieve a small viewing angle, but also tends to cause light crosstalk between adjacent chips.

### SUMMARY

Embodiments of the present application provide a display panel including: a driving substrate; a plurality of chips disposed on the driving substrate; a plurality of encapsulating colloids, where the plurality of encapsulating colloids corresponds to the plurality of chips in a one-to-one correspondence, and each of the plurality of encapsulating colloids covers each of the plurality of chips; and a dielectric layer disposed on the driving substrate, where the dielectric layer is formed on outer peripheries of the plurality of encapsulating colloids; and where the encapsulating colloid includes a substrate and a curved lens connected to each other, the substrate covers the chip, and the curved lens is disposed on a side of the substrate away from the chip.

In some embodiments, the dielectric layer is an air layer, and a refractive index of the encapsulating colloid is greater than a refractive index of the dielectric layer.

In some embodiments, the dielectric layer is a colloidal layer, and a refractive index of the encapsulating colloid is greater than a refractive index of the dielectric layer.

In some embodiments, the dielectric layer is a colloidal layer, the dielectric layer has a plurality of openings, each of the plurality of openings has the encapsulating colloid, the substrate is filled in the opening, and the curved lens is disposed on the side of the substrate away from the chip.

In some embodiments, the display panel further includes a reflective layer disposed on an inner wall of the opening.

In some embodiments, the display panel further includes a light-shielding layer disposed on a side of the dielectric layer away from the driving substrate, and the light-shielding layer is distributed between two adjacent encapsulating colloids of the plurality of encapsulating colloids.

In some embodiments, the display panel further includes a protective layer overlying the plurality of encapsulating colloids and the light-shielding layer, and a refractive index of the protective layer is smaller than a refractive index of the curved lens.

In some embodiments, a height of the substrate above the dielectric layer is a thickness of the light-shielding layer.

In some embodiments, the display panel further includes a distributed bragg reflection disposed between the driving substrate and the plurality of chips.

In some embodiments, the curved lens includes a Fresnel lens or a spherical lens.

In some embodiments, a sectional shape of the opening in a thickness direction of the dielectric layer is inverted trapezoidal.

The present application further provides a manufacturing method of display panel, including: providing a driving substrate; forming a plurality of chips on the driving substrate; forming a plurality of encapsulating colloids corresponding to the plurality of chips on the driving substrate; and forming a dielectric layer disposed on outer peripheries of the plurality of encapsulating colloids on the driving substrate; and where each of the plurality of encapsulating colloid includes a substrate and a curved lens connected to each other, the substrate covers each of the plurality of chips, and the curved lens is disposed on a side of the substrate away from the chip.

In some embodiments, the dielectric layer is an air layer, and a refractive index of the encapsulating colloid is greater than a refractive index of the dielectric layer.

In some embodiments, the dielectric layer is a colloidal layer, and a refractive index of the encapsulating colloid is greater than a refractive index of the dielectric layer.

In some embodiments, the dielectric layer is a colloidal layer, the dielectric layer has a plurality of openings, each of the plurality of openings has the encapsulating colloid, the substrate is filled in the opening, and the curved lens is disposed on the side of the substrate away from the chip.

In some embodiments, after the providing the driving substrate, the manufacturing method includes: forming the dielectric layer having the plurality of openings distributed in an array on the driving substrate; forming the plurality of chips on the driving substrate, where the chip is disposed in the opening; and forming the encapsulating colloid corresponding to the chip in the opening.

In some embodiments, after the forming the dielectric layer having the plurality of openings distributed in an array on the driving substrate, manufacturing method further includes: forming a reflective layer on an inner wall of the opening.

In some embodiments, the forming the dielectric layer having the plurality of openings distributed in an array on the driving substrate includes: forming a negative photoresist layer on the driving substrate; patterning the negative photoresist layer to form a plurality of through-holes; filling pixel defining material in each of the plurality of through-holes; and removing a remaining negative photoresist layer after patterning.

In some embodiments, the forming the encapsulating colloid corresponding to the chip in the opening includes: filling substrate material on the dielectric layer and in the opening, imprinting the substrate material by nano-imprinting, forming the curved lens on the chip and the substrate in the opening.

### Beneficial Effect

Advantageous effects of the present application are as follows: according to the display panel and the manufacturing method provided in the present application, the dielectric layer is provided on the driving substrate, the chips are disposed on the driving substrate in an array, and each encapsulating colloid covers each chip. Meanwhile, the substrate and the curved lens connected to each other are provided in the encapsulating colloid. As such, the lights generated by the chip exit at a small angle after being collimated by the curved lens, thereby realizing a small-angle display of the display panel.

### BRIEF DESCRIPTION OF THE DRAWINGS

In order that the embodiments or the technical solutions in the related art may be described more clearly, reference will now be made to the accompanying drawings which are to be used in the description of the embodiment. It should be understood that the accompanying drawings in the description below are merely some of the embodiments of the present application, and other drawings may be made to those skilled in the art without involving any inventive effort.

FIG. 1 is a schematic sectional diagram of a display panel according to an embodiment of the present application;

FIG. 2 is another schematic sectional diagram of a display panel according to an embodiment of the present application;

FIG. 3 is yet another schematic sectional diagram of a display panel according to an embodiment of the present application;

FIG. 4 is yet another schematic sectional diagram of a display panel according to an embodiment of the present application;

FIG. 5 is yet another schematic sectional diagram of a display panel according to an embodiment of the present application;

FIG. 6 is yet another schematic sectional diagram of a display panel according to an embodiment of the present application;

FIG. 7A and FIG. 7B are schematic sectional diagrams of an encapsulating colloid according to an embodiment of the present application;

FIG. 8 is a schematic flowchart of a manufacturing method of display panel according to an embodiment of the present application; and

FIG. 9A to FIG. 9J are schematic sectional diagrams of a display panel at different phases of a manufacturing method according to an embodiment of the present application.

### DETAILED DESCRIPTION OF THE EMBODIMENTS

The technical solution in the embodiments of the present application is clearly and completely described with reference to the accompanying drawings. It should be understood that the described embodiments are only part of the embodiments of the present application, and not all embodiments. Based on the embodiments in the present application, all other embodiments obtained by a person skilled in the art without involving any inventive effort are within the scope of the present application.

In the description of the present application, it should be understood that the orientation or positional relationship indicated by the terms “center”, “longitudinal”, “lateral”, “length”, “width”, “thickness”, “on”, “below”, “left”, “right”, “vertical”, “horizontal”, “top”, “bottom”, “in”, “out”, “clockwise”, “counterclockwise” and the like, is based on the orientation or positional relationship shown in the drawings, merely to facilitate the description of the present application and to simplify the description, and not to indicate or imply that the device or element referred to must have a particular orientation, be constructed and operated in a particular orientation, and therefore is not to be construed as limiting the present application. Thus, the terms are not indicated as the limitation to the present application. Furthermore, the terms “first” and “second” are used for descriptive purposes only and are not to be construed as indicating or implying relative importance or implying the number of indicated technical features. Thus, the features defined by “first” and “second” are indicated or implied to include one or more. In the description of this application, unless otherwise stated, “a plurality of” means two or more.

In the description of the present application, it should be noted that, unless expressly stated and defined otherwise, the terms “mount”, “link”, “connect” are to be understood in a broad sense, for example, as a fixed connection, as a detachable connection, or as an integrated connection; as a an electrical connection or a communication; as a directly connection or an indirectly connection by means of an intermediate medium; and as an internal communication or interaction of the two elements. The specific meaning of the above terms in the present application can be understood in a specific way to those of ordinary skill in the art.

In the present application, unless expressly stated and defined otherwise, the phase that a first element is “on” or “under” a second element may include that the first element is directly contacted with the second element, or the first element is indirectly contacted with the second element and is connected by another element therebetween. The phase that a first element is “on”, “over” or “above” a second element may include that the first element is directly above and obliquely above the second element, or merely indicate that the first element is higher than the second element. The phase that a first element is “under”, “below” or “neath” a second element may include that the first element is directly under and obliquely under the second element, or merely indicate that the first element is lower than the second element.

The following disclosure provides many different embodiments or examples for implementing the different structures of the present application. In order to simplify the disclosure of the present application, components and arrangements of specific examples are described below. Of course, they are merely examples and are not intended to limit the application. In addition, the present application may repeat reference numerals and/or reference letters in various instances, such repetition being for the purpose of simplicity and clarity, without itself indicating a relationship between the various embodiments and/or arrangements discussed. In addition, the present application provides examples of various specific processes and materials, but one of ordinary skill in the art will recognize the application of other processes and/or the use of other materials.

In the related art, a chip is disposed on a driving substrate, and a light-emitting angle of the chip is not less than 120°. Therefore, it is generally not easy to realize a small-angle display of the display panel, and after arranging a chip array, a crosstalk also occurs between lights emitted from two adjacent chips. To this end, embodiments of the present application provide a display panel to alleviate the above problems.

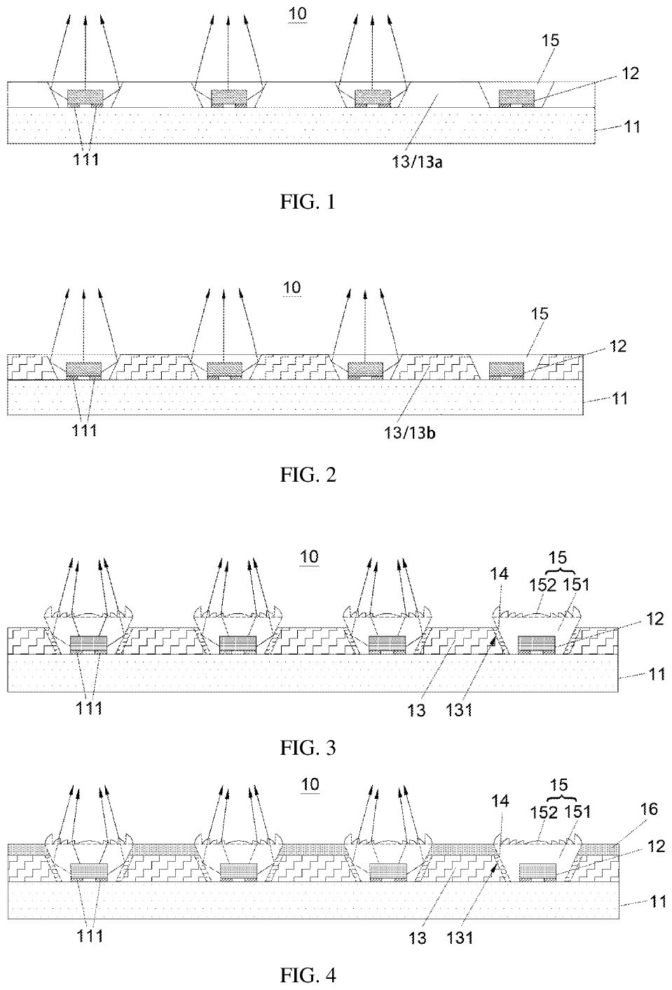

As shown in FIG. 1 and FIG. 2, a display panel 10 includes a driving substrate 11, a plurality of chips 12, a dielectric layer 13, and a plurality of encapsulating colloids 15. The driving substrate 11 is a thin film transistor (TFT) glass substrate, and the driving substrate 11 includes a driving circuit (not shown) and electrodes 111 corresponding to the chips 12. Each of the chips 12 is electrically connected to corresponding electrodes 111, so that the chips 12 are driven by the driving circuit of the driving substrate 11, and the chip 12 can be individually illuminated by the driving circuit. The plurality of encapsulating colloids 15 are in one-to-one correspondence with the plurality of chips 12, each of the encapsulating colloids 15 covers each of the chips 12. The dielectric layer 13 is provided on the driving substrate 11 and on outer peripheries of the encapsulating colloids 15. Meanwhile, referring to FIG. 3, each of the encapsulating colloids 15 includes a substrate 151 and a curved lens 152 connected to each other, the substrate 151 covers the chip 12, and the curved lens 152 is disposed on a side of the substrate 151 away from the chip 12. In this way, the divergence angle of the lights collimated through the encapsulating colloid 15 can be reduced by the refraction effect of the convex curve of the curved lens 152. As such, the viewing angle of the display panel 10 is reduced from 120° to 90° or below, thereby achieving the small-angle display of the display panel 10. At the same time, since the divergence angle of the lights emitted from the chip 12 are reduced after collimating through the encapsulating colloid 15, the problem of light crosstalk between two adjacent chips 12 is alleviated to some extent.

The dielectric layer 13 may be determined according to actual requirements, which is not limited in the embodiments of the present application. As shown in FIG. 1, in some embodiments, the dielectric layer 13 may be an air layer 13a, and the refractive index of the encapsulating colloid 15 is greater than the refractive index of the dielectric layer 13. Thus, the outer peripheral surface of the encapsulating colloid 15 may be directly contacted with the air layer 13a, and an interface is formed between the encapsulating colloid 15 and the air layer 13a. With the refractive index of the encapsulating colloid 15 being greater than the refractive index of the air layer 13a, in a case that the incident lights are irradiated to the interface between the encapsulating colloid 15 and the air layer 13a and the incident angle is greater than the critical angle, the incident lights are totally reflected at the interface and are emitted out of the encapsulating colloid 15.

As shown in FIG. 2, in other embodiments, the dielectric layer 13 may be a colloidal layer 13b, and the refractive index of the encapsulating colloid 15 is greater than the refractive index of the dielectric layer 13. With the refractive index of the encapsulating colloid 15 being greater than the refractive index of the colloidal layer 13b, in a case that the incident lights are irradiated to the interface between the encapsulating colloid 15 and the colloidal layer 13b and the incident angle is greater than the critical angle, the incident lights are totally reflected at the interface and are emitted out of the encapsulating colloid 15.

In the present application, when the chip 12 is energized to emit lights, the lights generated by the chip 12 may be irradiated in the encapsulating colloid 15. A part of the lights may exit directly from the side of the encapsulating colloid 15 away from the driving substrate 11; and a rest of the lights may be irradiated on the interface between the encapsulating colloid 15 and the dielectric layer 13. Since the refractive index of the encapsulating colloid 15 is greater than the refractive index of the dielectric layer 13, the rest of the lights are totally reflected at the interface between the encapsulating colloid 15 and the dielectric layer 13 in a case that the incident angle is greater than the critical angle, as such, the rest of the lights are then emitted out of the side of the encapsulating colloid 15 away from the substrate 11. In this way, the lights generated by the chip 12 are emitted out of the encapsulating colloid 15 relatively concentrically and does not emit out from the peripheral side of the encapsulating colloid 15. Thus, the lights are emitted out concentrically in the small viewing angle range in the encapsulating colloid 15, to realize the small viewing angle and to increase the light intensity and the contrast ratio at the required small viewing angle, which facilitates for the user to observe and satisfies the display requirement having the specific angle of viewing such as a head up display.

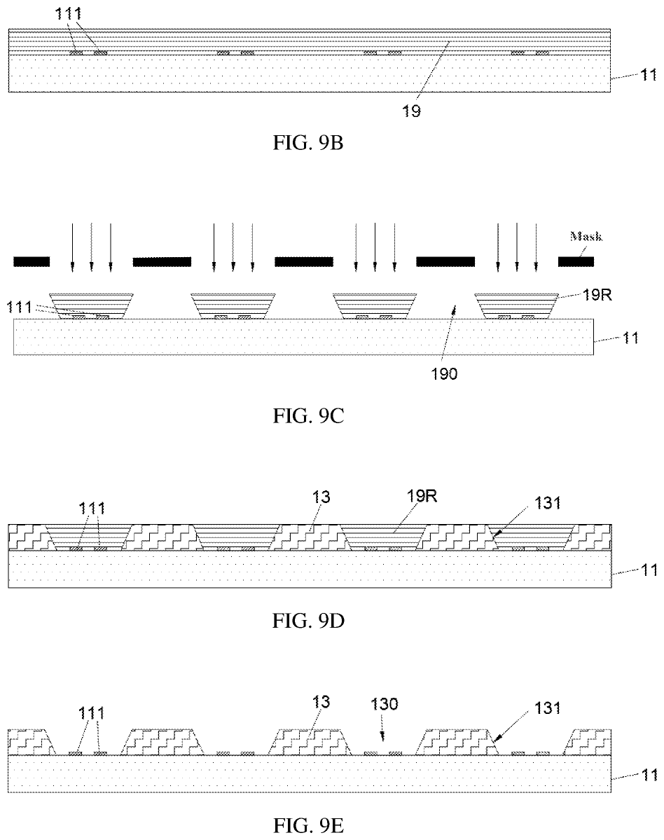

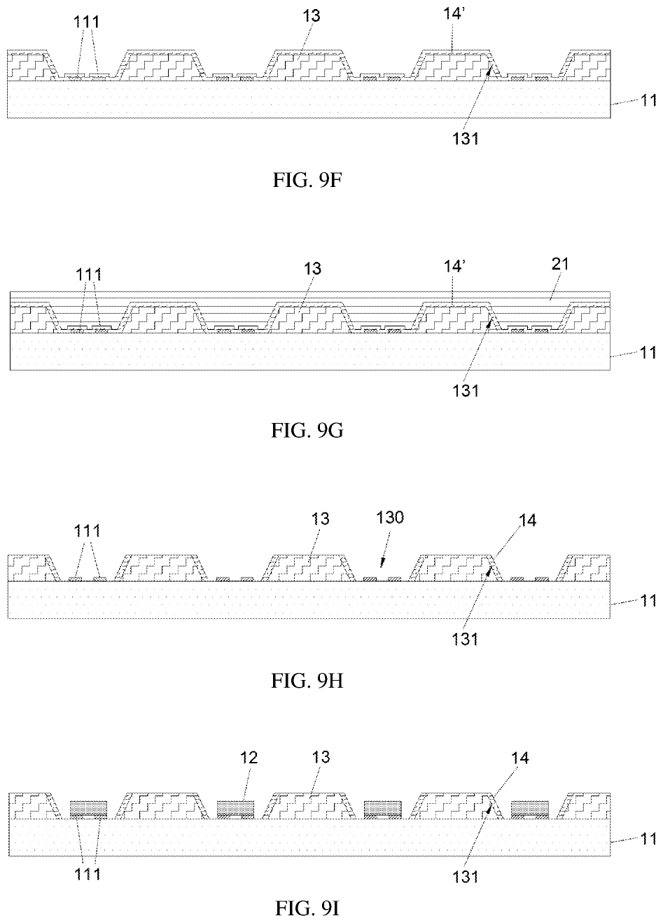

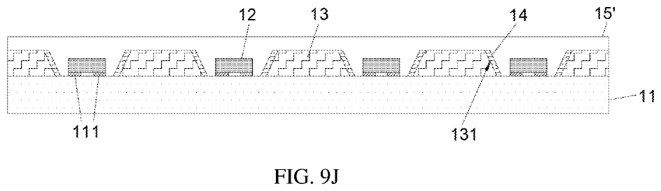

In some embodiments, in a case that the dielectric layer 13 is a colloid layer, and the dielectric layer 13 may have a plurality of openings 130 arranged in an array (combined with FIG. 9H). Each of the chips 12 is disposed in each of the openings 130, so that the plurality of chips 12 are arranged in an array on the drive substrate 11. Meanwhile, as shown in FIG. 3, each of the encapsulating colloids 15 is provided in each of the openings 130, the substrate 151 is filled in the opening 130, and the curved lens 152 is provided on the side of the substrate 151 away from the chip 12.

Further, as shown in FIG. 3, the display panel 10 may further include a reflective layer 14 disposed on an inner wall 131 of each of the openings 130. Since the reflective layer 14 is provided on the inner wall 131 of each of the openings 130, the lights emitted from the chip 12 to the inner wall 131 are reflected by the reflective layer 14, thereby changing the propagation path of the lights. As such, the lights originally irradiated at the larger angle can be emitted out at the smaller angle by the reflection of the reflective layer 14. In an embodiment, the material of the reflective layer 14 may include metallic material, such as silver or other metallic material having the effect of reflecting lights. Further, in order to enable the reflective layer 14 to reflect lights outwardly rather than inwardly. In the present embodiment, it is preferable that the cross-sectional shape of the opening 130 in the thickness direction of the dielectric layer 13 is the inverted trapezoid, that is, the width of the side of the opening 130 close to the driving substrate 11 is smaller than the width of the side of the opening 130 away from the driving substrate 11.

Since the inner wall 131 of the opening 130 is provided with the reflective layer 14, and the opening 130 is filled with the encapsulating colloid 15. A part of the lights generated by the chip 12 exit at the small angle after collimating through the curved lens 152 of the encapsulating colloid 15. For another part of the lights, the propagation path of the lights irradiated on the curved lens 152 is changed after reflecting by the reflective layer 14, and the lights are then collimated through the curved lens 152 to exit at the small angle. As such, the small-angle display of the display panel is achieved.

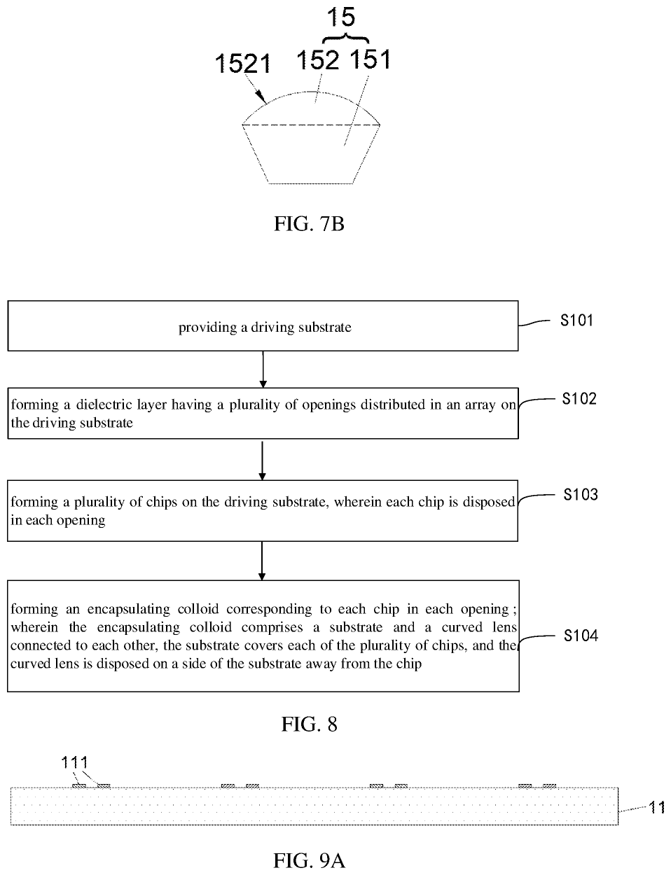

FIG. 7A is a schematic sectional diagram of the encapsulating colloid 15 according to an embodiment of the present application. As shown in FIG. 7A, a light-emitting surface 1521 of the curved lens 152 includes a convex curved surface. The curved lens 152 may include a Fresnel lens as shown in FIG. 7A, and an elliptical arcuate surface of a central portion of the Fresnel lens in FIG. 7A corresponds to the convex curved surface. FIG. 7B is another schematic sectional diagram of the encapsulating colloid 15 according to an embodiment of the present application. As shown in FIG. 7B, the curved lens 152 may include a spherical lens as shown in FIG. 7B, and a spherical surface of the spherical lens shown in FIG. 7B corresponds to the convex curved surface. The convex curved surface can refract in the way of in-focusing different lights, thereby achieving the effect of reducing the divergence angle of the lights.

It should be further noted that the encapsulating colloid 15 is integrally molded, and the dashed lines indicated in FIG. 7A and FIG. 7B define the boundary line between the curved lens 152 and the substrate 151, and do not indicate that the substrate 151 is detachably connected to the curved lens 152. In the present embodiment, the substrate 151 and the curved lens 152 are made of the same material, and may include an epoxy resin. In a case that the material of the substrate 151 includes epoxy resin, the substrate 151 adhesively secures the chip 12 in the opening 130.

In some embodiments, referring to FIG. 4, an embodiment of the present application also provides another schematic sectional diagram of the display panel 10. The display panel 10 shown in FIG. 4 further includes a light-shielding layer 16 disposed on a side of the dielectric layer 13 away from the driving substrate 11, and the light-shielding layer 16 is distributed between two adjacent encapsulating colloids 15.

The light-shielding layer 16 may include a black epoxy resin or other light-opaque material. The light-shielding layer 16 serves to enhance the contrast of the display panel 10, improve the display effect of the display panel 10, and further solve the problem of light crosstalk in the display panel 10.

The area between the two adjacent encapsulating colloids 15 is a non-light-emitting area, and more lights in the non-light-emitting area causes the display panel 10 to have a lower contrast. In order to improve the contrast, the light-shielding layer 16 absorbs all of or most of the lights emitted from the chip 12 to the non-light-emitting area. As such, the contrast of the display panel 10 can be improved, and interference of the lights emitted from the two adjacent chips 12 in the non-light-emitting area can be avoided, thereby further solving the problem of light crosstalk in the display panel 10.

In some embodiments, a height of the substrate 151 above the dielectric layer 13 is equal to a thickness of the light-shielding layer 16.

By setting the height of the substrate 151 above the dielectric layer 13 being equal to the thickness of the light-shielding layer 16, the lights emitted from the chip 12 can change the propagation path after being reflected by the reflective layer 14, so that the lights originally emitting to the reflective layer 14 at the large divergence angle can exit at the small angle after being reflected, while the other lights emitting to the non-light-emitting area at the large divergence angle can be absorbed by the light-shielding layer 16. As such, the contrast of the display panel 10 is improved.

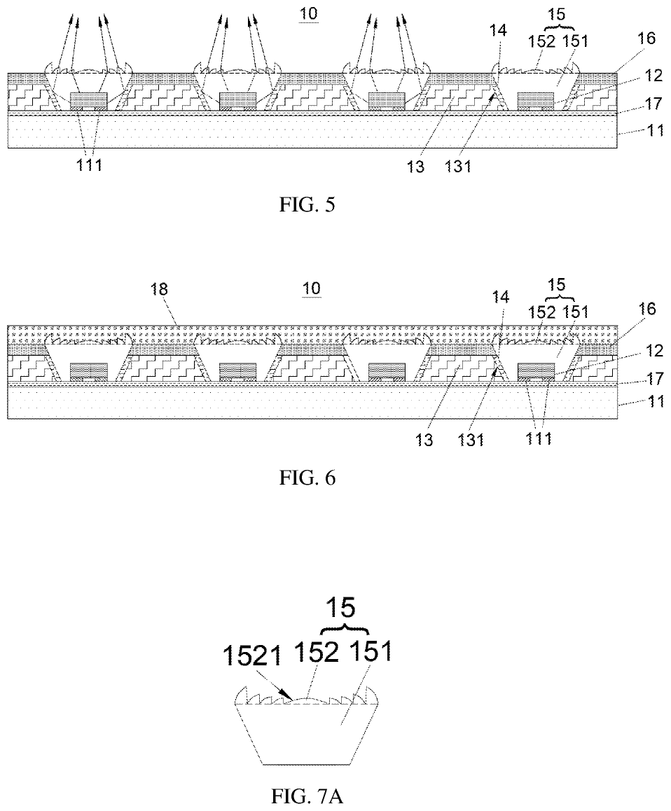

In some embodiments, referring to FIG. 5, an embodiment of the present application also provides another schematic sectional diagram of the display panel 10. The display panel 10 shown in FIG. 5 further includes a distributed bragg reflection (DBR) 17 disposed between the driving substrate 11 and the plurality of chips 12. It should be noted that the arrangement of the distributed bragg reflection 17 is not necessarily associated with the arrangement of the light-shielding layer 16. Therefore, in the present embodiment, the distributed bragg reflection 17 may be added directly to the structure shown in FIG. 3.

The distributed bragg reflection 17 functions to reflect upward the lights emitted from the bottom surface of the chip 12, that is, the lights emitted from the chip 12 toward the substrate 11 is reflected in a direction away from the substrate 11, thereby improving the utilization rate of the lights emitted from the chip 12, and further improving the luminous brightness of the display panel 10. The distributed bragg reflection 17 is a periodic structure in which two different refractive index materials are alternately arranged, and the optical thickness of each layer is ¼ of the central reflection wavelength, corresponding to a group of photonic crystals. The reflectivity of the distributed bragg reflection 17 can reach 99% or more due to the impenetrability of electromagnetic waves of which the frequencies fall in the energy gap. In the present embodiment, the distributed bragg reflection 17 may include titanium oxide and silicon oxide materials. Since the distributed bragg reflection 17 does not include a metal material, there is no absorption problem in the distributed bragg reflection 17 compared with the metal reflector, and the reflection effect of the distributed bragg reflection 17 is better than that of the metal reflector.

In some embodiments, referring to FIG. 6, an embodiment of the present application also provides another schematic sectional diagram of the display panel 10. The display panel 10 shown in FIG. 6 also includes a protective layer 18. It should be noted that the arrangement of the protective layer 18 is not necessarily associated with the arrangement of the distributed bragg reflection 17, and therefore, in the present embodiment, the protective layer 18 may be added directly to the structure shown in FIG. 4.

The protective layer 18 serves to ensure the flatness of the display panel 10 and to further reduce the light-emitting angle of the chip 12. The protective layer 18 covers the plurality of encapsulating colloids 15 and the light-shielding layer 16, and the refractive index of the protective layer 18 is smaller than the refractive index of the curved lens 152.

The refractive index of the protective layer 18 preferably ranges from 1 to 1.41, and the refractive index of the curved lens 152 preferably ranges from 1.54 to 2. By setting the refractive index of the protective layer 18 being less than the refractive index of the curved lens 152, when the lights enter the protective layer 18 through the curved lens 152, the divergence angle of the lights can be further reduced based on the refraction law of being incident from the medium having the high refractive index to the medium having the low refractive index.

Based on the above-described display panel, an embodiment of the present application further provides a manufacturing method of display panel. Referring to FIG. 1 to FIG. 2, the manufacturing method may include: providing a driving substrate 11; forming a plurality of chips 12 on the driving substrate 11; forming an encapsulating colloid 15 corresponding to each of the plurality of chips 12 on the driving substrate 11; and forming a dielectric layer 13 on the driving substrate 11 and on outer peripheries of the encapsulating colloids 15. Referring to FIG. 3, each of the encapsulating colloids 15 includes a substrate 151 and a curved lens 152 connected to each other, the substrate 151 covers the chip 12, and the curved lens 152 is disposed on a side of the substrate 151 away from the chip 12.

In some embodiments, the dielectric layer 13 may be an air layer or a colloidal layer, and the refractive index of the encapsulating colloid 15 is greater than the refractive index of the dielectric layer 13. In a case where the dielectric layer 13 is a colloidal layer, the dielectric layer 13 may have a plurality of openings 130, and each of the encapsulating colloids 15 is disposed in each of the openings 130. Meanwhile, in a case where the dielectric layer 13 is a colloidal layer, as shown in FIG. 8 (combined with FIG. 2), the manufacturing method may further include: providing a driving substrate 11; forming a dielectric layer 13 with a plurality of openings 130 distributed in an array on the driving substrate 11; forming a plurality of chips 12 on the driving substrate 11, and each of the plurality of chips 12 is disposed in each of the plurality of openings 130; and forming an encapsulating colloid 15 corresponding to each of the plurality of chips 12 and in each of the plurality of openings 130. Each of the plurality of encapsulating colloids 15 includes a substrate connected and a curved lens connected to each other, the substrate covers the chip, and the curved lens is disposed on a side of the substrate away from the chip.

Hereinafter, steps S101-S104 of the manufacturing method shown in FIG. 8 are described by using the dielectric layer 13 as a colloidal layer as an example. Note that the following steps can still be applicable to the case where the dielectric layer 13 is an air layer.

In step S101, a driving substrate is provided.

The sectional structure of the display panel after step S101 is shown in FIG. 8A.

The driving substrate 11 is a thin film transistor (TFT) glass substrate, and the driving substrate 11 includes a driving circuit (not shown) and electrodes 111. The electrodes 111 are used to electrically connect the driving substrate 11 to the chip 12 (shown in FIG. 9I). A DBR (not shown in FIG. 9A, see reference numeral 17 in FIG. 5 to FIG. 6) is also formed on the driving substrate. The DBR is formed between the electrodes and the driving substrate 11, and may be formed on the driving substrate 11 by evaporation.

In step S102, a dielectric layer with a plurality of openings 130 distributed in an array on the driving substrate 11 are formed.

The step S102 may include the following steps.

In a first step, a negative photoresist layer 19 is formed on the driving substrate 11.

The sectional structure of the display panel after the first step is shown in FIG. 9B.

The negative photoresist layer 19 may be coated on the driving substrate 11 by a spin coating method. The negative photoresist layer 19 includes a long-chain polymeric organic material. For example, the negative photoresist layer 19 may include cis-polyisoprene and a radiation-sensitive crosslinking agent.

In a second step, the negative photoresist layer 19 is patterned to form a plurality of through-holes 190.

The sectional structure of the display panel after the second step is shown in FIG. 9C.

The negative photoresist layer 19 is patterned by exposing the negative photoresist layer 19 with a mask having a predetermined pattern, and removing a portion of the negative photoresist layer 19 after the exposure. The negative photoresist layer 19 including cis-polyisoprene and a radiation-sensitive crosslinking agent is taken as an example. The exposed cis-polyisoprene is crosslinked by the crosslinking agent to form a bulk polymer which is cured and insoluble in the developing solution, and a portion (not shown) of the unexposed negative photoresist layer 19 is dissolved in the developing solution (xylene) so as to be removed to form the opening 190, and a portion of the exposed negative photoresist layer 19 remains on the driving substrate 11 to form the remaining negative photoresist layer 19R. The remaining negative photoresist layer 19R is used to cover the electrodes 111 to avoid damage to the electrodes 111 in a subsequent process, and the remaining negative photoresist layer 19R is also used to be removed in a subsequent process to form an opening for accommodating a light-emitting device.

In this embodiment, according to the characteristics of the negative photoresist layer 19, the exposure amount at the top of the negative photoresist layer 19 is relatively large, the width at the top of the negative photoresist layer 19 after development is relatively large; and the exposure amount at the bottom of the negative photoresist layer 19 after development is relatively small, the width at the bottom of the negative photoresist layer 19 after development is relatively small; thereby forming an inverted trapezoidal structure of the remaining negative photoresist layer 19R shown in FIG. 9C. The height of the inverted trapezoid structure ranges from 20 μm to 50 μm.

In a third step, the through-hole 190 is filled with pixel defining material.

The sectional structure of the display panel after the third step is shown in FIG. 9D.

The pixel defining material may include an epoxy resin. The pixel defining material is filled in the through-hole 190 to form a dielectric layer 13 on the substrate 11. Here, the process of filling the pixel defining material in the through-hole 190 generally includes covering a layer of pixel defining material on the remaining negative photoresist layer 19R, and therefore, the process of filling the pixel defining material in the through-hole 190 further includes removing excess pixel defining material outside the through-hole 190, thereby exposing the surface of the remaining negative photoresist layer 19R.

In a fourth step, the remaining negative photoresist layer 19R is removed.

The sectional structure of the display panel after the fourth step is shown in FIG. 9E.

Since the remaining negative photoresist layer 19R after development in the second step is the inverted trapezoidal structure, a plurality of openings 130 are formed in the dielectric layer 13 after removing the remaining negative photoresist layer 19R. The openings 130 have an inverted trapezoidal structure in sectional shape along the thickness direction of the dielectric layer 13 and expose the electrodes 111.

After the step S102, the manufacturing method may further include forming a reflective layer 14 on an inner wall 131 of each of the openings 130.

The forming the reflective layer 14 on the inner wall 131 of each of the openings 130 may include the following steps.

In a first step, a reflective material 14′ is deposited on the surface of the dielectric layer 13, the inner wall 131 of the opening 130, and the driving substrate 11 without being covered the dielectric layer 13. The sectional structure of the display panel after the first step is shown in FIG. 9F.

The reflective material 14′ may include a metallic material, such as silver or other reflective material. In a case that the reflective material 14′ is selected as silver, it may be deposited by evaporation. It should be further noted that, since the electrodes 111 are also provided on the driving substrate 11, a part of the reflective material 14′ is also deposited on the electrodes 111 and needs to be removed in a subsequent process.

In a second step, a positive photoresist layer 21 is formed on the reflective material 14′. The sectional structure of the display panel after the second step is shown in FIG. 9G.

The positive photoresist layer 21 includes diazoquinone and an alkali-soluble phenolic resin.

In a third step, the positive photoresist layer 21 is patterned to remove the positive photoresist layer on the bottom of the opening 130.

The exposed positive photoresist layer 21 can be removed by the developing solution containing an alkaline substance such as sodium hydroxide. In a case that the positive photoresist layer 21 includes diazoquinone and an alkali-soluble phenolic resin, the diazoquinone degrades after exposure and is dissolved in the developing solution together with the phenolic resin. In the step of patterning the positive photoresist layer 21, the positive photoresist layer 21 on the inner wall 131 is selectively reminded, while the positive photoresist layer 21 on the top of the dielectric layer 13 is also selectively reminded, alternatively, only the positive photoresist layer 21 on the inner wall 131 is selectively reminded.

In a fourth step, the reflective material 14′ without being covered the positive photoresist layer 21 is removed.

Since the positive photoresist layer 21 is covered at least on the reflective material 14′ on the inner wall 131 after patterning, the reflective material 14′ without being covered the positive photoresist layer 21 is etched to remove by inductively coupled plasma (ICP) etching process using the remaining positive photoresist layer 21 as a mask, thereby forming the reflective layer 14 on at least the inner wall 131 of the opening 130. By removing the reflective material 14′ on the bottom of the opening 130, it is possible to remove the reflective material 14′ overlying the electrodes 111, thereby avoiding circuit short of the electrodes 111 is case of the reflective material 14′ as conductive material, or preventing a non-electric-connection between the chip and the electrode 111 in case of the reflective material 14′ as insulative material.

Since the positive photoresist layer 21 may alternatively be remined on top of the dielectric layer 13, the reflective layer 14 may also be formed on top of the dielectric layer 13. It should be further noted that, in a case that the reflective layer 14 is selected to be formed only on the inner wall 131 of the opening 130, the dielectric layer 13 may be bonded in direct contact with a subsequent substrate material to facilitate the subsequent coating of the substrate material on the dielectric layer 13, due to no reflective layer 14 on the top of the dielectric layer 13.

In a fifth step, the positive photoresist layer 21 overlying the remaining reflective material 14′ is removed. The sectional structure of the display panel after the fifth step is shown in FIG. 9H.

In step S103, a plurality of chips arranged in an array are formed on the driving substrate, and each of the plurality of chips is disposed in each of the plurality of openings.

The sectional structure of the display panel after the step S103 is shown in FIG. 9I.

The chip 12 with the solder on the surface is transferred to the electrodes 111 of the driving substrate 11 by the elastic mucosa with the protrusion on the surface, and the chip 12 is heated to melt the solder, as such, the chip 12 is soldered to the electrodes to realize the electrical connection between the chip 12 and the electrodes 111 on the driving substrate 11. Thereafter, the elastic mucosa is removed to transfer the chip 12 to the driving substrate 11.

In step S104, an encapsulating colloid corresponding to each of the plurality of chips and in each of the plurality of openings is formed. The encapsulating colloid includes a substrate connected and a curved lens connected to each other, the substrate covers the chip, and the curved lens is disposed on a side of the substrate away from the chip.

The sectional structure of the display panel after the step S104 can be referred to the sectional structures shown in FIG. 3 to FIG. 6.

The step S104 may be divided into a step of filling substrate material in the opening 130 and a step of forming a curved lens on the substrate material. On the basis of FIG. 9I, the substrate material 15′ may be filled on the dielectric layer 13 and in the openings 130. The sectional structure of the display panel after this step is shown in FIG. 9J. Thereafter, the substrate material 15′ is imprinted by nano-imprinting using a mold with curved pits, to form the curved lens 152 on the chip 12 and the substrate 151 in the opening 130. As such, the sectional structure of the display panel shown in FIG. 3 is formed.

In this embodiment, before step S103, the manufacturing method may further include forming a light-shielding layer 16 on the dielectric layer 13, and the light-shielding layer 16 is formed by nano-imprinting. Therefore, the sectional structures of the display panel shown in FIG. 4 to FIG. 5 can be finally formed by the manufacturing method.

In this embodiment, after step S104, the manufacturing method may further include forming a protective layer 18 on the encapsulating colloid 15 and the light-shielding layer 16. Therefore, the sectional structure of the display panel shown in FIG. 6 can be finally formed by the manufacturing method.

According to the display panel and the manufacturing method provided in the present application, the dielectric layer having a plurality of openings is provided on the driving substrate, the chips are provided on the driving substrate in an array, and each encapsulating colloid covers each chip. In this way, the lights generated by the chip are concentrated in the small angle range defined by the encapsulating colloid, and the small viewing angle can be achieved. In addition, the lights generated by the chip may further exit at the small angle after being collimated by the curved lens of the encapsulating colloid, thereby improving the small-angle display of the display panel.

There may be other embodiments of the present application in addition to the above-described embodiments. The technical solutions defined by the equivalents fall in the scope of protection of the present application.

As above, although the embodiments have been disclosed in the present application, the above embodiments are not intended to limit the present application, and those of ordinary skill in the art may make various changes and modifications without departing from the spirit and scope of the present application, and therefore the scope of protection of the present application is as defined in the claims.

1. A display panel, comprising:
a driving substrate;
a plurality of chips disposed on the driving substrate;
a plurality of encapsulating colloids, wherein the plurality of encapsulating colloids corresponds to the plurality of chips in a one-to-one correspondence, and each of the plurality of encapsulating colloids covers each of the plurality of chips; and
a dielectric layer disposed on the driving substrate, wherein the dielectric layer is formed on outer peripheries of the plurality of encapsulating colloids; and
wherein the encapsulating colloid comprises a substrate and a curved lens connected to each other, the substrate covers the chip, and the curved lens is disposed on a side of the substrate away from the chip.

2. The display panel of claim 1, wherein the dielectric layer is an air layer, and a refractive index of the encapsulating colloid is greater than a refractive index of the dielectric layer.

3. The display panel of claim 1, wherein the dielectric layer is a colloidal layer, and a refractive index of the encapsulating colloid is greater than a refractive index of the dielectric layer.

4. The display panel of claim 1, wherein the dielectric layer is a colloidal layer, the dielectric layer has a plurality of openings, each of the plurality of openings has the encapsulating colloid, the substrate is filled in the opening, and the curved lens is disposed on the side of the substrate away from the chip.

5. The display panel of claim 4, wherein the display panel further comprises a reflective layer disposed on an inner wall of the opening.

6. The display panel of claim 1, wherein the display panel further comprises a light-shielding layer disposed on a side of the dielectric layer away from the driving substrate, and the light-shielding layer is distributed between two adjacent encapsulating colloids of the plurality of encapsulating colloids.

7. The display panel of claim 6, wherein the display panel further comprises a protective layer overlying the plurality of encapsulating colloids and the light-shielding layer, and a refractive index of the protective layer is smaller than a refractive index of the curved lens.

8. The display panel of claim 6, wherein a height of the substrate above the dielectric layer is a thickness of the light-shielding layer.

9. The display panel of claim 1, wherein the display panel further comprises a distributed bragg reflection disposed between the driving substrate and the plurality of chips.

10. The display panel of claim 1, wherein the curved lens comprises a Fresnel lens or a spherical lens.

11. The display panel of claim 4, wherein a sectional shape of the opening in a thickness direction of the dielectric layer is inverted trapezoidal.

12. A manufacturing method of display panel, comprises:
providing a driving substrate;
forming a plurality of chips on the driving substrate;
forming a plurality of encapsulating colloids corresponding to the plurality of chips on the driving substrate; and
forming a dielectric layer disposed on outer peripheries of the plurality of encapsulating colloids on the driving substrate; and
wherein each of the plurality of encapsulating colloid comprises a substrate and a curved lens connected to each other, the substrate covers each of the plurality of chips, and the curved lens is disposed on a side of the substrate away from the chip.

13. The manufacturing method of claim 12, wherein the dielectric layer is an air layer, and a refractive index of the encapsulating colloid is greater than a refractive index of the dielectric layer.

14. The manufacturing method of claim 12, wherein the dielectric layer is a colloidal layer, and a refractive index of the encapsulating colloid is greater than a refractive index of the dielectric layer.

15. The manufacturing method of claim 12, wherein the dielectric layer is a colloidal layer, the dielectric layer has a plurality of openings, each of the plurality of openings has the encapsulating colloid, the substrate is filled in the opening, and the curved lens is disposed on the side of the substrate away from the chip.

16. The manufacturing method of claim 15, wherein after the providing the driving substrate, the manufacturing method comprises:
forming the dielectric layer having the plurality of openings distributed in an array on the driving substrate;
forming the plurality of chips on the driving substrate, wherein the chip is disposed in the opening; and
forming the encapsulating colloid corresponding to the chip in the opening.

17. The manufacturing method of claim 16, wherein after the forming the dielectric layer having the plurality of openings distributed in an array on the driving substrate, manufacturing method further comprises:
forming a reflective layer on an inner wall of the opening.

18. The manufacturing method of claim 16, wherein the forming the dielectric layer having the plurality of openings distributed in an array on the driving substrate comprises:
forming a negative photoresist layer on the driving substrate;
patterning the negative photoresist layer to form a plurality of through-holes;
filling pixel defining material in each of the plurality of through-holes; and
removing a remaining negative photoresist layer after patterning.

19. The manufacturing method of claim 16, wherein the forming the encapsulating colloid corresponding to the chip in the opening comprises:
filling substrate material on the dielectric layer and in the opening, imprinting the substrate material by nano-imprinting, forming the curved lens on the chip and the substrate in the opening.
